(19) United States
(12) Patent Application Publication
(10) Pub. No.: US 2003/0113974 A1
(43) Pub. Date: Jun. 19, 2003

(54) Stacked metal-insulator-metal capacitor structures in between interconnection layers

(76) Inventors: Xian J. Ning, Mohegan Lake, NJ (US); Yi-Sheng Hsieh, Hsin-Chu (TW)

Correspondence Address: HOGAN & HARTSON L.L.P., 500 S. GRAND AVENUE, SUITE 1900, LOS ANGELES, CA, 90071-2611, US

(21) Appl. No.: 10/017,149

(22) Filed: Dec. 14, 2001

(51) Int. Cl. H01L 21/20

(52) U.S. Cl. 438/379

(57) ABSTRACT

A parallel capacitor structure that can be fabricated using advanced processing techniques that employ, for example, copper interconnects and low k dielectrics is described. The parallel capacitor structure includes a first copper dual Damascene interconnection line, a first interconnection, a middle capacitor electrode, a dielectric layer, a second interconnection, an upper capacitor electrode, and a second interlayer dielectric layer. The existing first copper dual Damascene interconnection line is embedded in a first interlayer dielectric layer, and is utilized as a lower capacitor electrode. The middle capacitor electrode is on the first copper dual Damascene interconnection line. The dielectric layer is interposed between the first copper dual Damascene interconnection line and the middle capacitor electrode. The second interconnection can be directly connected to the middle capacitor electrode. The first interconnection connects the upper capacitor electrode to the first copper dual Damascene interconnection line. The second interlayer dielectric layer is interposed between the middle capacitor electrode and the upper capacitor electrode. When a potential having a first polarity is applied to the upper capacitor electrode and to the first copper dual Damascene interconnection line, and a potential having a second polarity, opposite the first polarity, is applied to the middle capacitor electrode, this structure functions as a parallel capacitor. By using an existing first copper dual Damascene interconnection line as a lower capacitor electrode, the capacitance per unit area can be increased without substantially increasing manufacturing complexity.

### BACKGROUND OF THE INVENTION

The present invention relates to metal-insulator-metal capacitors for integrated circuits and methods for manufacturing the same.

Manufacturing high density and high speed integrated circuits presents a range of challenges, many of which are interrelated. In many present designs, the speed of an integrated circuit is limited to a large extent by interconnects and wiring structures of the type conventionally formed in what are known as back end of the line (“BEOL”) processes. Various aspects of BEOL interconnects and wiring lines contribute to limited performance. High density integrated circuits tend to use small cross section wiring lines, which are more resistive than larger wiring lines and which are spaced more closely together. The higher resistivity of these smaller wiring lines contributes to delays in the integrated circuit. There has consequently been interest in reducing the resistance of wiring lines.

Recent developments in copper wiring technology have allowed for significant enhancements in the performance of many electronic products, such as personal computers, cell phones and video games, while reducing the number of chips needed in these products thereby making products smaller and less expensive.

In particular, aspects of present integrated circuits that allow faster circuit operation are the use of copper interconnects and low k dielectrics. Copper interconnects can be used for some or all of the interconnects in an integrated circuit and provide an approximately thirty percent reduction in wiring line resistance as compared to similar aluminum wiring lines. Less resistive wiring lines allow signals to propagate faster. In addition to the propagation speed benefits, the use of copper wiring also provides benefits for reduced levels of heat generation.

Low k dielectrics refer to a class of materials that have a dielectric constant lower than the silicon oxide insulation historically used in integrated circuits. Use of low k dielectric materials reduces the capacitive and inductive coupling between adjacent wiring lines, which can limit the performance of high-density integrated circuits. As wiring lines are spaced more closely together, the capacitive and inductive coupling between adjacent wiring lines increases, thereby slowing the circuit and making propagation delays undesirably long. Reducing the dielectric constant of the material used to insulate between wiring lines reduces the level of coupling between adjacent wiring lines and allows signals to propagate at higher speeds with lower coupling losses. A number of low dielectric constant (i.e., “low k”) materials are presently being considered and used, at least on an experimental basis. Many of these materials incorporate significant proportions of open space or air through the presence of small pores in the insulating layer. Because air has a low dielectric constant, forming insulating layers with significant levels of porosity is an effective strategy for producing a layer of low dielectric constant material.

Logic circuits that process information and memory circuits that store information have traditionally been used in concert to add “intelligence” to electronic products. Conventionally, logic circuits and memory circuits have normally been provided on separate chips, adding complexity and cost. However, recent advances in semiconductor technology have allowed complete electronic systems to be built on a single silicon chip.

System-On-a-Chip (SOC) technology can be used to combine stand-alone chips along with other functions onto a single customized system-on-a-chip. For instance, it is now possible to combine both logic circuits for processing information and memory circuits for storing information on a single chip. By placing logic and memory together on a single chip, the logic circuitry can operate more efficiently. These advances can also allow for vast increases in integration density and memory that are available in a single chip. In turn, this can allow for a reduction of the number of chips used in electronic products which can result in even smaller, faster, more powerful, and lower-power electronic products by reducing the size, cost and power consumption of products in which SOC designs are used.

SOC technology has recently provided custom chips for emerging communications and consumer applications. Consumer appliances such as multi-media appliances and hand-held computing devices, voice over IP wireless handsets, and other advanced communications products, such as Webphones, Web tablets, home information terminals, and e-mail terminals are just a few of the many areas in which SOC technology has been implemented. Other innovative electronic devices that could make use of SOC technology include, for example, digital TVs, Internet-capable digital audio stereo sets, video recorders with hard disk drives or recordable DVDs, residential gateways, and utility telemeters.

“Mixed-mode” or mixed-signal products generally refer to products that include both analog and logic circuits. Mixed-mode products are widely used in Radio-Frequency (RF) devices implemented in wireless communications products such as cellular telephones. For example, SOC mixed-signal chips utilize both digital and analog signals within the same chip making it necessary to incorporate higher-frequency analog circuitry. Accordingly, there is a need for integrated circuit components, such as capacitors, that are better adapted for use in mixed-mode applications.

Integrated circuit capacitors that exhibit predictable and reliable electrical characteristics can be particularly useful in the context of mixed signal and radio frequency microelectronic circuits and devices. Such devices may require capacitors with low voltage coefficients (change of capacitance with voltage over an operating voltage range), good capacitor matching, and relatively predictable capacitor values. Mixed mode integrated circuit (IC) products can include components such as capacitors and inductors in addition to transistors and resistors.

One of the capacitor structures useful in higher-frequency applications, mixed mode signal processing, and system-on-a-chip applications can include Metal-Insulator-Metal CAPacitor (MIMCAP) structures. Thin-film MIMCAP structures generally include two substantially parallel layers of conductive material separated by an insulating layer. For example, MIMCAPs can be built in a back-end-of-line (BEOL) interconnect level with a bottom metal plate and a top metal plate that sandwich a capacitor dielectric layer in between those plates. The capacitor dielectric layer can be parallel to a semiconductor wafer surface. Metal plates of MIMCAPs have relatively low plate sheet resistance. As a result, the capacitors have relatively low series resistance, which allows capacitors with a relatively large Q factor. Capacitors with large Q factors can be useful in RF circuits. MIMCAPs also can allow for increased distance between the metal layers and the substrate (i.e., the base plate may be formed above the substrate surface) thereby reducing parasitic capacitance. MIMCAPs also generally have lower voltage coefficients due to reduced voltage induced depletion effects at the metal-to-insulator interface.

One technique for reducing the size of capacitors used in devices and circuits is to increase the capacitor's capacitance density by using insulating layers with higher dielectric constants and/or by reducing the thickness of the insulating layer (i.e., the distance between the top and base plate of the capacitor). For a given dielectric material, breakdown voltage parameters are generally dependent upon, among other things, the minimum distance between conducting layers. As surface roughness of either the insulating layer or the conducting layers increases, the insulating layer thickness may have to be increased so that the thinnest portion of the insulating layer will still provide adequate breakdown voltage characteristics.

Both copper wiring lines and low k interlayer dielectrics are difficult to manufacture reliably and cost effectively. Nevertheless, the advantages of structures made with these processes are sufficient as to encourage investment and use. In addition to presenting difficult materials and processing problems, it is difficult to integrate copper interconnects and low k dielectrics. Different strategies have been proposed, including the structure illustrated in FIGS. 9 and 10.

A publication by R. Liu et al. entitled “Single Mask Metal-Insulator-Metal (MIM) Capacitor with Copper Damascene Metallization for Sub-0.18 μm Mixed Mode Signal and System-On-a-Chip (SoC) Applications” appearing in Proc. 2000 IITC, pp. 111-113 (2000) is herein incorporated by reference in its entirety. FIG. 9, which correspond to a reproduction of FIG. 3 of this publication, illustrates conventional MIMCAP structure built in a copper damascene level. As shown in FIG. 9, this MIMCAP structure was implemented in an interlayer dielectric 310 using an existing copper Damascene level as a bottom plate 320, a barrier layer 340 comprising silicon nitride dielectric, and a top electrode 350. However, this structure can suffer from a variety of drawbacks. For example, the electrode plates of this particular MIMCAP structure plates are parallel to the wafer and hence take relatively large chip area. In addition, this MIMCAP structure would require a relatively thin dielectric layer to provide a relatively high capacitance, which may increase the risk of leakage between the electrode plates.

A publication by M. Arnacost et al. entitled “A High Reliability Metal Insulator Metal Capacitor for 0.18 μm Copper Technology” appearing in Technical Digest 2000 IEDM pp. 157-160. (2000) is herein incorporated by reference in its entirety. As shown in FIG. 10, this publication discussed a MIMCAP structure that could be integrated into copper dual Damascene interconnects 500 using an aluminum bottom plate 440, a silicon oxide dielectric 450, and a TiN top plate 460. However, this structure requires an additional AL stack as bottom plate which increases the process complexity and costs.

### SUMMARY OF THE PREFERRED EMBODIMENTS

An aspect of the present invention provides a method of forming an integrated circuit. A first interlayer dielectric layer is provided. A first trench and a via are then formed in the first interlayer dielectric layer. The first trench and via are then filled with a conductor to provide lower capacitor electrode. A dielectric film is then deposited, and a patterned electrode is provided thereon. A patterned second interlayer dielectric layer is then provided having a first via, a second via, and an upper capacitor electrode. The upper capacitor electrode is connected to the lower capacitor electrode by the first via. The second via is connected to the middle capacitor electrode.

Another aspect of the present invention provides an integrated circuit including an embedded metal-insulator-metal capacitor (MIMCAP). The circuit includes a lower capacitor electrode, a first conductive via, a middle capacitor electrode, a dielectric layer interposed between the lower capacitor electrode and the middle capacitor electrode on the lower capacitor electrode, a second conductive via directly connected to the middle capacitor electrode, an upper capacitor electrode, and a second interlayer dielectric layer interposed between the middle capacitor electrode and the upper capacitor electrode. The lower capacitor electrode has a copper surface coplanar with a surface of a first interlayer dielectric layer laterally surrounding the lower capacitor electrode. The upper capacitor electrode is surrounded laterally by the second interlayer dielectric layer. The first conductive via connects the upper capacitor electrode to the lower capacitor electrode.

### BRIEF DESCRIPTION OF DRAWINGS

The following discussion may be best understood with reference to the various views of the drawings, described in summary below, which form a part of this disclosure.

FIG. 1 schematically illustrates a capacitor structure of an integrated circuit device in accordance with a preferred aspect of the present invention.

FIG. 2 schematically illustrates another capacitor structure of an integrated circuit device in accordance with another preferred aspect of the present invention.

FIGS. 3 through 6 illustrate capacitor structures of integrated circuit devices shown in FIGS. 1 and 2 at various intermediate stages of processing.

FIGS. 7 through 8 illustrate capacitor structures of integrated circuit devices shown in FIGS. 1 and 2, respectively, at various intermediate stages of processing.

FIG. 9 illustrates a conventional capacitor structure.

FIG. 10 illustrates another conventional capacitor structure.

### DETAILED DESCRIPTION OF THE PREFERRED EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element such as a layer, region or substrate is referred to as being “on” another element, it can be directly on the other element or intervening elements may also be present. In contrast, when an element is referred to as being “directly on” another element, there are no intervening elements present. It will also be understood that when an element such as a layer, region or substrate is referred to as being “over” another element, it can be directly over the other element or intervening elements may also be present. In contrast, when an element is referred to as being “directly over” another element, there are no intervening elements present. It will also be understood that when an element such as a layer, region or substrate is referred to as being “connected to” or another element, it can be directly connected to the other element or intervening elements may also be present. In contrast, when an element is referred to as being “directly connected to” another element, there are no intervening elements present. When an element such as a layer, region or substrate is referred to as being “adjacent” another element, it can be near the other element but not necessarily independent of the other element. When an element such as a layer, region or substrate is referred to as being “between” two things, it can be either partly of completely between those two things, but is not necessarily completely and continuously between those two things. The term “adapted to” should be construed to mean “capable of”. As used herein, the term “opening” may refer to openings such as vias, trenches, grooves, contact holes and the like. As used herein the term “portion” covers pieces that are either separate or integral, whereas “separate portion” covers pieces that are separate only.

As used herein, unless noted otherwise, the terms insulating, insulative, or insulator may include any material that is resistant to the conduction of electricity. Examples of insulators can include, for example, doped or undoped silicon oxide or nitride, silicon oxynitride, tantalum oxide, barium strontium titanate, phosphosilicate glass, tetraethylorthosilane (undoped or doped with boron and/or phosphorous), low-k dielectric materials such as spin on dielectrics, fluorinated oxides, or the like.

As used herein, unless noted otherwise, the terms conducting, conductive or conductor may include any material capable of conducting electricity. Examples of conductors include, for example, doped silicon substrate, polysilicon, doped polysilicon, and metals including, but not limited to, tungsten, aluminum, copper, titanium, titanium nitride, any combination thereof, or the like. Each of the preferred implementations described and illustrated herein will be described with reference to copper technology, however, the embodiments described herein are equally applicable to other types of low resistivity conductors as well.

Integrated circuits including copper wiring lines and low k interlayer dielectrics have considerable advantages for performance, but can be complicated to manufacture. For example, the fabrication of capacitor structures implemented in such integrated circuits can require many complicated process steps. It may be desirable to increase the capacitance per unit area provided by such capacitor structures.

Aspects of the present invention provide a capacitor structure adapted to advanced processing techniques. Aspects of the present invention can also provide methods of forming a MIMCAP structure that require few additional steps (e.g., deposition, masking, and etching steps) that are specific to MIMCAP formation. Capacitor structures produced according to aspect of the invention described below can help to reduce the number of additional processing steps needed to manufacture capacitor structures, while also increasing the capacitance per unit area of the resultant capacitor structure. Moreover, the methods described below can allow MIMCAP structures to be formed or implemented at various metallization levels within the integrated circuit.

Aspects of the present invention also provide a capacitor structure useful in analog applications and better adapted to advanced processing techniques. The MIMCAP structures are useful in, for example, Radio Frequency (RF) applications. MIMCAP structures can also be implemented, for example, in between a digital circuit and an analog circuit for decoupling in packages using both types of circuits.

Implementations of the present invention can provide an integrated circuit including an embedded MIMCAP structure. Aspects of the present invention provide capacitor structures better adapted to advanced processing techniques. Preferred implementations of the present invention utilize dual Damascene manufacturing techniques to define a lower capacitor electrode and Damascene manufacturing techniques to define the upper capacitor electrode. This strategy defines the extent of the upper capacitor electrode by patterning the dielectric layer. Accordingly, a MIMCAP structure can be defined without masking and etching a metal layer.

In a preferred implementation, a lower capacitor electrode is defined by forming a first trench in a dielectric layer, depositing metal to fill the trench and polishing to define the lateral extent of the lower electrode. Another dielectric is provided, and a middle capacitor electrode is disposed on the dielectric over the lower capacitor electrode. Another dielectric layer is then provided having an upper capacitor electrode embedded therein. For example, in certain preferred implementations, a trench is formed at least partially on the capacitor lower electrode, and a conductor is deposited to fill the trench and removed by polishing to define the extent of the upper capacitor electrode. The lower capacitor electrode and the upper capacitor electrode are electrically coupled

Preferred implementations of the present invention provide parallel stacked metal-insulator-metal capacitor (MIMCAP) structures that utilize existing Damescene interconnect level metal wiring lines as plates of the parallel MIMCAP structures. Preferred implementations of the present invention also provide a middle plate electrode between the existing dual Damescene interconnect level metal wiring lines to provide parallel MIMCAP structures. In comparison to the fabrication of a single MIMCAP structure, the parallel MIMCAP structures can be fabricated without using additional process steps. By constructing two parallel MIM capacitors the capacitance can be up to two times as high as that of a similarly constructed single MIMCAP. Because capacitance per unit area is increased, valuable chip area can be saved and/or the thickness of a dielectric layer in the MIMCAP can be reduced. As a result, yield can be improved.

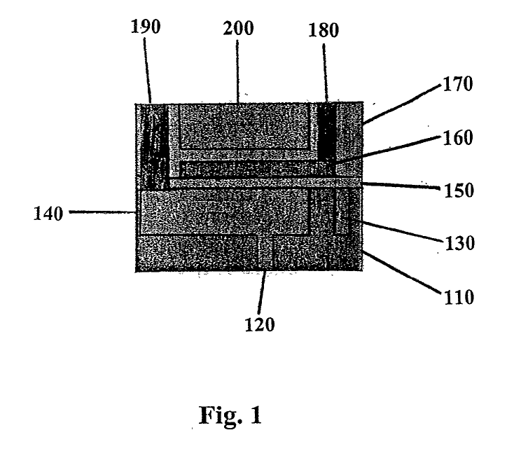

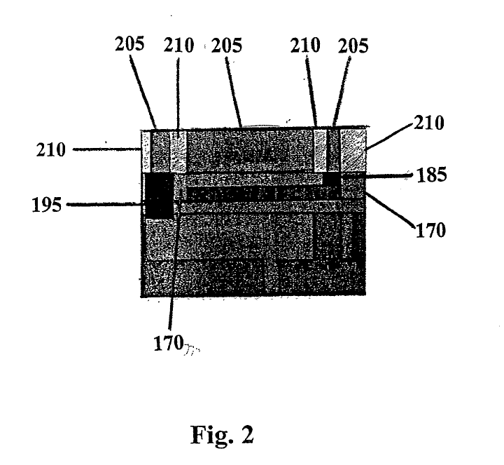

FIGS. 1 and 2 schematically illustrate capacitor structures of an integrated circuit device in accordance with preferred aspects of the present invention. As shown in FIGS. 1 and 2, an integrated circuit including an embedded MIMCAP structure can be provided that includes a lower capacitor electrode comprising a first copper dual Damascene interconnection line 120, 140, a first interconnection 190, 195, 205, a middle capacitor electrode 160, a dielectric layer 150, a second interconnection 180, 185, 205, an upper capacitor electrode 200, 205, and a second interlayer dielectric layer 170.

The lower capacitor electrode 120, 140 is embedded in a first interlayer dielectric layer 110, and is located in an area defined by the first interconnection 190, 195/205, and the second interconnection. In the embodiments shown in FIGS. 1 and 2, the lower capacitor electrode 120, 140 is located below the middle capacitor electrode 160, beneath the upper capacitor electrode 200, 205, and above the first interlayer dielectric layer 110. This first dual Damascene interconnection line 120, 140 preferably comprises copper and has a thickness between 1500 and 4000 Å.

The dielectric layer 150 is interposed between the first copper dual Damascene interconnection line 120, 140 and the middle capacitor electrode 160.

The middle capacitor electrode 160 is on at least part of the lower capacitor electrode 120, 140. Generally, the middle capacitor electrode 160 is located in a region defined by the first interconnection 190, 195/205, the second interconnection 180, 185/205, the first copper dual Damascene interconnection line 120, 140, and the upper capacitor electrode 200, 205. In the embodiment shown in FIG. 1, the upper capacitor electrode 200 comprises a second copper Damascene interconnection line. The middle capacitor electrode 160 comprises a metal such as AL, TiN, Ti, W, Ta, and TaN. The middle capacitor electrode 160 preferably has a thickness between 300 and 1500 Å.

The second interlayer dielectric layer 170 is interposed between the middle capacitor electrode 160 and the upper capacitor electrode 200, 205.

In one of a number of possible arrangements, FIG. 1 illustrates that the upper capacitor electrode 200 comprises a second Damascene interconnection line. The upper capacitor electrode 200, 205 is located between the first conductive plug and the second conductive plug. In the embodiment shown in FIG. 1, the upper capacitor electrode 200, 205 preferably comprises copper. By contrast, in the embodiment shown in FIG. 2, the upper capacitor electrode 205 can be made of aluminum. In both cases, the upper capacitor electrode 200, 205 preferably has a thickness between 1000 and 10000 Å.

In the embodiment shown in FIG. 1, the first interconnection 190 may comprise a single conductive plug 190 that is also preferably made of copper. The conductive plug directly connects the first copper dual Damascene interconnection line 120, 140 to the upper electrode 200. By contrast, in the embodiment shown in FIG. 2, the first interconnection may comprise a first contact 195 preferably made of tungsten and a first conductive plug 205 preferably fabricated from aluminum. The first interconnection 195/205 connects the upper capacitor electrode 205 to the first copper dual Damascene interconnection line 120, 140.

In both FIG. 1 and FIG. 2, the second interconnection 180, 185/205 is directly connected to the middle capacitor electrode 160. For example, in FIG. 1, the second contact 180 is directly coupled to the middle capacitor electrode 160, whereas in FIG. 2, the second interconnection may comprise a second contact 185 that couples a second conductive plug 205 to the middle capacitor electrode 160.

In the embodiments shown in FIGS. 1 and 2, the entire parallel MIMCAP structure is located within a region defined by the space between the first interconnection 190, 195/205 and the second interconnection 180, 185/205.

As shown in FIGS. 1 and 2, an integrated circuit including an embedded MIMCAP structure can be provided that includes a first capacitor structure (not labeled), a first interconnection 190, 195/205, a second interconnection 180, 185/205, and a second capacitor structure (not labeled). The parallel MIMCAP capacitor structure is thus defined by the first copper dual Damascene interconnection line 120, 140, middle capacitor electrode 160, and upper capacitor electrode 200, 205.

In particular, the first capacitor structure comprises the middle capacitor electrode 160, the dielectric layer 150, and the first dual Damascene interconnection line. The first dual Damascene interconnection line preferably comprises a back-end-of-line (BEOL) interconnect layer comprising copper. The first interconnection 190, 195/205 is directly connected to the first dual Damascene interconnection line 120/140 to the upper capacitor electrode 200, 205. The second interconnection 180, 185/205 is directly connected to the middle capacitor electrode 160. The middle capacitor electrode 160 is located within a region defined by the first dual Damascene interconnection line 120/140 and the upper capacitor electrode 200, 205.

The second capacitor structure (not labeled) comprises the upper capacitor electrode 200, 205, the interlayer dielectric layer 150, and the middle capacitor electrode 160. The second capacitor structure (not labeled) is connected in parallel to the first capacitor structure (not labeled). The upper capacitor electrode 200, 205 can comprise, for example, a copper Damascene interconnection line 200 or an aluminum plate 205. When aluminum technology is used in implementing the second capacitor structure, the upper capacitor electrode 200, 205 can comprise an aluminum line electrode, and the first interconnection 190, 195/205 and the second interconnection 180, 185/205 can both comprise a tungsten contact 195, 185 coupled to an aluminum via 205.

Although not shown, additional levels of interconnects and wiring lines are provided to form successive levels of copper interconnects and wiring lines.

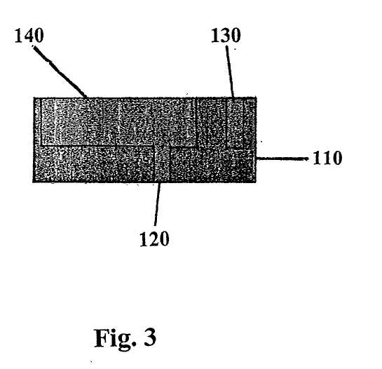

The method of making the capacitor structures of the integrated circuit devices shown in FIGS. 1 and 2 will now be described. FIGS. 3 through 8 illustrate various intermediate stages of processing during the manufacture of capacitor structures of the integrated circuit devices shown in FIGS. 1 and 2.

Although not shown in FIG. 3, a substrate is provided that includes various circuits and other components formed in and/or on its surface. The structure shown in FIG. 3 represents subsequent levels above the substrate at an intermediate stage of production. In the particular embodiment shown in FIG. 3, a interlayer dielectric layer 110 having a first copper dual Damescene interconnection line 120, 140 embedded therein is provided. This is accomplished by providing a first interlayer dielectric layer 110, and forming a dual Damescene opening (not shown) in the first interlayer dielectric layer 110.

A first interlayer dielectric (ILD) layer 110 is formed, most preferably of a low dielectric constant (low k) material. There are a number of different low k materials, including aerogels and the porous dielectric sold by the Dow Corning Corporation. Preferred low k dielectrics often are organic materials and preferably have a significant level of porosity. This discussion is made in terms of a particularly preferred low k material sold under the trademark SiLK by the Dow Chemical Company of Midland, Mich. The SiLK dielectric material is applied in a spin on process to a desired thickness appropriate for forming metal wiring lines. The spun on SiLK material is initially cured and then baked to complete formation of the first interlayer dielectric (ILD) layer 110.

In the illustrated embedded MIMCAP, a lower capacitor electrode is formed of copper in a dual Damascene process so as to be in contact with another interconnect layer. The first stage of the dual Damascene process is defining the trench and via openings in the first level ILD 110. Low k ILD layer 110 preferably is patterned using a dual hard mask process, typically using a layer of CVD silicon nitride as a lower hard mask and a layer of CVD silicon oxide as an upper hard mask. The two hard mask layers are deposited and then the upper hard mask is patterned, using photoresist in a conventional photolithography process, to define the lateral extent of the trench. The lower hard mask is patterned second to define the lateral extent of the via to be formed. Because the upper hard mask is thin, the second, lower hard mask can be patterned using photoresist in a conventional photolithographic process because the first mask does not introduce too large of a step. In a preferred implementation, the lower capacitor electrode 120, 140 is defined by providing a first patterned mask on the first interlayer dielectric layer 110, and etching away portions of the first interlayer dielectric layer 110 to form a first groove 120 in the interlayer dielectric layer 110. The first patterned mask is then removed, and the opening (not shown) is completed by providing a second patterned mask (not shown) on the first interlayer dielectric layer 110, and etching away other portions (not shown) of the first interlayer dielectric layer 110 that reside over the groove (not shown) to form a trench 140.

After clean up, a conductor can then be deposited to fill the via and the trench. A first conductive layer (not shown) that preferably consists essentially of copper can then be deposited to form the lower capacitor electrode 120, 140. First, a liner layer is deposited, for example, a titanium nitride layer formed by chemical vapor deposition. After the liner layer is deposited, it preferably is annealed. After an appropriate liner layer is formed, a physical vapor deposition process such as sputtering or evaporation forms a copper seed layer within the vias and the trench opening. This process typically also deposits a liner layer and seed layer on the surface of the low k ILD layer 110 outside of the trench and via. Copper is then electrodeposited within the vias and trench to form the lower capacitor electrode 120, 140.

The first conductive layer (not shown) can then be planarized by chemical mechanical polishing (CMP) the first conductive layer (not shown) until the first conductive layer (not shown) is flush with a surface of the first interlayer dielectric layer 110 to define the lateral extent of the lower capacitor electrode 120, 140. Chemical mechanical polishing (CMP) produces a planarized surface that is smooth and flat. It may be desirable to make the surface flat to reduce topography differences and to have even thickness of metal lines embedded in the ILD. In preferred implementations, the copper is annealed and then chemical mechanical polishing is performed to remove excess copper, seed layer and liner layer from the surface of the ILD layer 110.

The remaining portions 120, 130, 140 of the first conductive layer (not shown) comprise a metallization 130 and the first copper dual Damescene interconnection line 120, 140 that is adapted to serve as a lower capacitor electrode of a first capacitor structure. The lower capacitor electrode 120, 140 includes a copper surface coplanar with a surface of a first interlayer dielectric layer laterally surrounding the lower capacitor electrode.

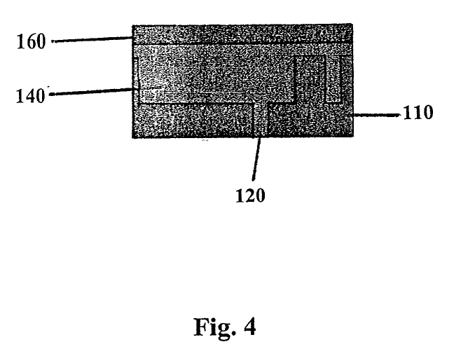

In the processing that takes place between FIG. 3 and FIG. 4, a dielectric film 150 is then deposited, for example, by plasma enhanced chemical vapor depositing (PECVD) a silicon nitride film to a thickness between 500 Å and 1500 Å.

As shown in FIG. 4, a second conductive layer 160 is deposited. The second conductive layer 160 can comprise a metal. For example, TiN, W, TaN, Al, Cu, Ta, Ti or any other conductors could be used. The second conductive layer 160 is preferably deposited to a thickness between 300 Å and 1500 Å. The thickness of the second conductive layer 160 can be substantially equal to a thickness of the dielectric film 150.

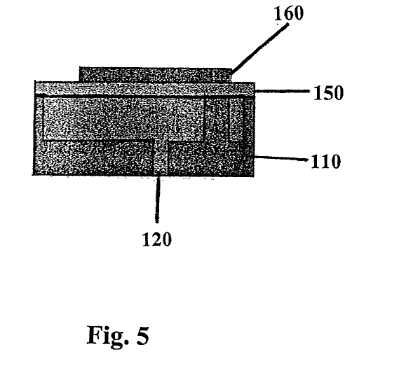

In the processing that takes place between FIGS. 4 and 5, a lithographic mask pattern (not shown) is provided on the second conductive layer 160. The second conductive layer 160 is then etched such that the remaining portion of the second conductive layer 160 comprises a plate adapted to be used as a middle capacitor electrode 160. The second conductive layer 160 can be etched, for example, using reactive ion etching (RIE) to transfer the pattern of the lithographic mask pattern to the second conductive layer 160. The middle capacitor electrode 160 is located above the first copper dual Damescene interconnection line 120, 140, and as will be discussed herein, below the upper electrode 200, 205. The middle capacitor electrode 160 is adapted to function as a top electrode of a first capacitor structure and a bottom electrode of a second capacitor structure. The residue (not shown) from the etching step is then cleaned away.

Optionally, a high k dielectric layer (not shown), such as silicon nitride layer, may then be deposited to a thickness between 500 Å and 1500 Å. As shown in FIG. 5, a second interlayer dielectric layer 170 is then provided, for example, by spinning on a liquid low K dielectric such as SiLK and then curing the dielectric. This may result in a porous dielectric layer 170. The second interlayer dielectric layer 170 preferably has a thickness between 3000 Å and 10000 Å.

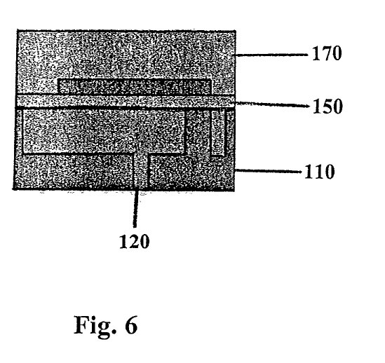

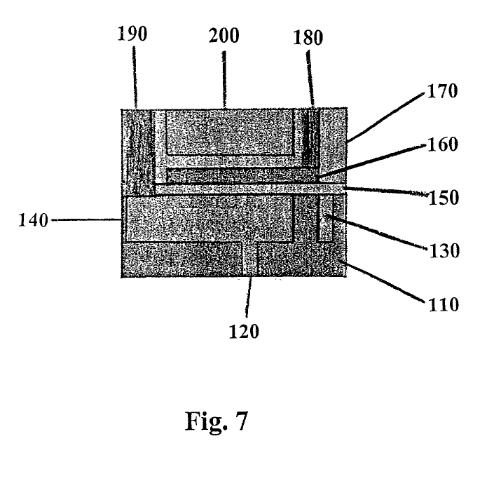

In the processing that takes place between FIGS. 6 and 7, a trench is provided in the interlayer dielectric layer and is filled with a conductor to provide an upper capacitor electrode. An upper capacitor electrode is surrounded laterally by the second interlayer dielectric layer and has a substantially planar face separated from at least a portion of the lower capacitor electrode by a capacitor dielectric layer.

In particular, a third patterned mask (not shown) is provided on the second interlayer dielectric layer 170, and portions of the second interlayer dielectric layer 170 are etched away to form, for example, a first via opening (not shown) and a second via opening (not shown) therein. The third patterned mask is removed from the surface to the second interlayer dielectric layer 170, and a fourth patterned mask (not shown) is provided on the second interlayer dielectric layer 170. Other portions of the second interlayer dielectric layer 170 can then be etched away to form a Damescene interconnection line opening (not shown) therein. A Damascene process is used to define and form the trench for the Damascene process in the dielectric layer 170. The fourth patterned mask may then be removed from the surface of the second interlayer dielectric layer 170.

In the embodiment shown in FIG. 7, a third conductive layer (not shown) that preferably consists essentially of copper may then be deposited to simultaneously fill the first via opening, the second via opening, and the second Damescene interconnection line opening. When the conductor comprises copper, the copper line 200 is formed in the conventional manner by depositing a liner within the trench, forming a seed layer within the trench and then electrodepositing copper within the trench. The third conductive layer may then be planarized by, for example, chemical mechanical polishing (CMP) until the third conductive layer is flush with a surface of the second interlayer dialectic layer 170. The remaining portions 180, 190, 200 of the third conductive layer comprise a copper Damescene interconnection line 200, a first via 190 adapted to connect the first copper dual Damescene interconnection line 120, 140 and the second copper Damescene interconnection line 200, and a second via 180 connected to the middle electrode plate 160.

Thus, as shown in FIG. 7, a patterned second interlayer dielectric layer 170 is provided having a first via 190, a second via 180, and a second interconnection line 200 embedded therein. The first copper dual Damescene interconnection line 120, 140 is adapted to serve as a bottom capacitor electrode. The first copper dual Damescene interconnection line 120, 140 has a via portion 120 and a line portion 140. The second interconnection line 200 preferably comprises a second copper Damescene interconnection line 200 adapted to be used as a top capacitor electrode. The second interconnection line 200 is connected to the first copper dual Damescene interconnection line 120, 140 by the first via 190. The second via 180 is connected to the middle capacitor electrode 160. The first copper dual Damescene interconnection line 120, 140 and the second copper Damescene interconnection line 200 are located between the first via 190 and the second via 180.

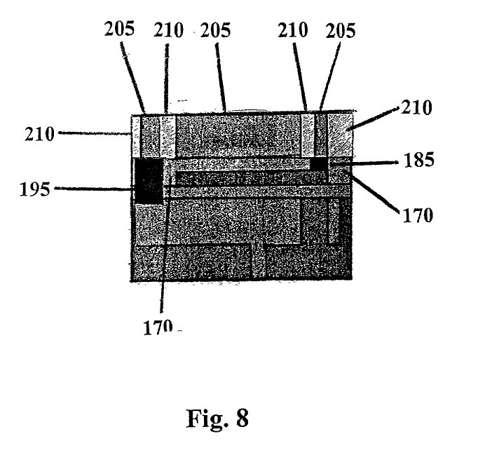

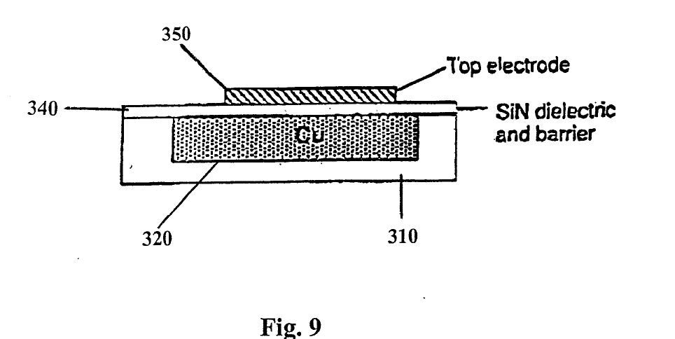

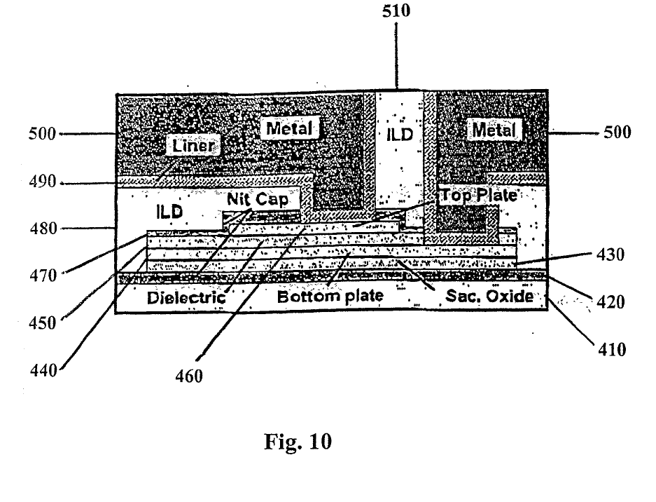

In the processing that takes place between FIGS. 6 and 8, a second interlayer dielectric layer 170 and a third patterned mask (not shown) on the second interlayer dielectric layer 170 are successively deposited. Portions of the second interlayer dielectric layer 170 can then be etched away to form a first via opening (not shown) to the first copper dual Damescene interconnection line 120, 140 and a second via opening (not shown) to the middle capacitor electrode 160. The third patterned mask can then be removed from the surface to the second interlayer dielectric layer 170, and a third conductive layer (not shown) can then be deposited to simultaneously fill the first via opening and the second via opening. The third conductive layer can be made of, for example, tungsten, aluminum, copper, and/or alloys thereof. Tungsten may be deposited by chemical vapor deposition. The third conductive layer can then be planarized by chemical mechanical polishing (CMP) until the third conductive layer is flush with a surface of the second interlayer dielectic layer 170. The remaining portions 195, 185 comprise a first via 195 connected to the first copper dual Damescene interconnection line 120, 140, and a second via 185 connected to the middle capacitor electrode 160. Although it is not shown, it is typical to form a barrier layer and an adhesion layer within the contact opening as part of the tungsten plug formation process.

A fourth conductive layer (not shown) is then provided, and a fourth patterned mask (not shown) is provided on the fourth conductive layer. The fourth conductive layer preferably consists essentially of aluminum. Portions of the fourth conductive layer can then be etched away by reactive ion etching such that remaining portions 205 of the fourth conductive layer comprise a first interconnection 205 connected to the first via 195, a top capacitor electrode 205 above the middle capacitor electrode 160, and a second interconnection 205 connected to the second via 185. The fourth patterned mask can then be removed. In contrast to the strategy shown in FIG. 7, the processing of the parallel MIMCAP structure shown in FIG. 8 requires deposition of an additional third interlayer dielectic layer 250 to complete the parallel MIMCAP structure. The third interlayer dielectric layer 150 can be deposited to simultaneously fill spaces adjacent the first interconnection 205, the top capacitor electrode 205, and the second interconnection 205. The third interlayer dielectric layer 250 functions to prevent cross talk between adjacent ones of the first interconnection 205, the top capacitor electrode 205, and the second interconnection 205. Again, the third interlayer dielectric layer 150 is preferably deposited in a liquid or semi-liquid form using a spin on process to help ensure even distribution of the dielectric material. While a wide range of dielectric materials may be used, preferably low K dielectrics such as porous SiLK are used.

As a result, a patterned second interlayer dielectric layer 170 having a first via 195/205, a second via 185/205, and a second interconnection line 205 embedded therein is provided. The second interconnection line 205 is connected to the first copper dual Damescene interconnection line 120, 140 by the first via 195/205, and the second via 185/205 is connected to the middle capacitor electrode 160.

As noted above, implementations of the present invention can provide an integrated circuit including MIMCAP structures. Aspects of the present invention can provide capacitor structures better adapted to advanced processing techniques. Preferred implementations of the present invention provide parallel stacked metal-insulator-metal capacitor (MIMCAP) structures that utilize existing Damescene interconnect level metal wiring lines as plates of the parallel MIMCAP structures. Preferred implementations of the present invention also provide a middle plate electrode between the existing dual Damescene interconnect level metal wiring lines to provide parallel MIMCAP structures. In comparison to the fabrication of a single MIMCAP structure, the parallel MIMCAP structures can be fabricated without using additional process steps. By constructing two parallel MIM capacitors the capacitance can be up to two times as high as that of a similarly constructed single MIMCAP. Because capacitance per unit area is increased, valuable chip area can be saved and/or the thickness of a dielectric layer in the MIMCAP can be reduced. As a result, yield can be improved.

While the present invention has been described in terms of certain preferred embodiments, those of ordinary skill in the will appreciate that certain variations, extensions and modifications may be made without varying from the basic teachings of the present invention. As such, the present invention is not to be limited to the specific preferred embodiments described herein. Rather, the scope of the present invention is to be determined from the claims, which follow.

What is claimed is:

1. A method of forming an integrated circuit, comprising:
providing a first interlayer dielectric layer;
forming a first trench and a via in the first interlayer dielectric layer and filling the first trench and via with a conductor to provide lower capacitor electrode;
depositing a dielectric film;
providing a patterned a middle capacitor electrode; and
providing a patterned second interlayer dielectric layer having a first via, a second via, and an upper capacitor electrode, wherein the upper capacitor electrode is connected to the lower capacitor electrode by the first via, and wherein the second via is connected to the middle capacitor electrode.

2. A method of according to claim 1, wherein the lower capacitor electrode has a copper surface coplanar with a surface of the first interlayer dielectric layer laterally surrounding the lower capacitor electrode.

3. A method of according to claim 1, wherein the upper capacitor electrode is surrounded laterally by the second interlayer dielectric layer and has a substantially planar face separated from at least a portion of the middle capacitor electrode by the second interlayer dielectric layer.

4. A method of according to claim 1, wherein the conductor is copper.

5. A method of according to claim 1, wherein the lower capacitor electrode comprises a first copper dual Damascene interconnection line adapted to be used as an electrode.

6. A method of according to claim 1, wherein the upper capacitor electrode comprises a an interconnection line adapted to be used as an electrode.

7. A method of according to claim 6, wherein the upper capacitor electrode comprises a copper Damascene interconnection line.

8. A method of according to claim 1, wherein the middle capacitor electrode is located between the lower capacitor electrode and the upper capacitor electrode.

9. A method of according to claim 1, wherein the lower capacitor electrode and the upper capacitor electrode are located between the first via and the second via.

10. A method of according to claim 1, wherein the lower capacitor electrode includes a via portion and a line portion.

11. A method of according to claim 1, forming a first trench and a via in the first interlayer dielectric layer and filling the first trench and via with a conductor to provide lower capacitor electrode, comprises:
providing a first patterned mask on the first interlayer dielectric layer;
etching away portions of the first interlayer dielectric layer to form a groove therein;
removing the first patterned mask from the surface to the first interlayer dielectric layer to form the via;
providing a second patterned mask on the first interlayer dielectric layer;
etching away other portions of the first interlayer dielectric layer to thereby form a trench over the via in the first interlayer dielectric layer;
depositing a first conductive layer consisting essentially of copper; and
chemical mechanical polishing the first conductive layer until the first conductive layer is coplanar with a surface of the first interlayer dielectric layer, wherein the remaining portions of the first conductive layer comprise the lower capacitor electrode adapted to serve as a bottom capacitor electrode of a first capacitor structure.

12. The method according to claim 11, wherein depositing a first conductive layer consisting essentially of copper:
depositing a liner layer;
forming a copper seed layer on the liner layer; and
electroplating copper within the trench to define, at least in part, a lower capacitor electrode.

13. A method of according to claim 1, wherein depositing a dielectric film comprises:
plasma enhanced chemical vapor depositing a silicon nitride dielectric film having a thickness between 500 Å and 1500 Å.

14. A method of according to claim 1, wherein providing a patterned a middle capacitor electrode on the lower capacitor electrode comprises:
depositing a second conductive layer;
providing a mask pattern on the second conductive layer; and
etching the second conductive layer such that the remaining portion of the second conductive layer comprises a middle capacitor electrode.

15. A method of according to claim 14, wherein the second conductive layer comprises a metal selected from the group consisting of TiN, W, TaN, Al, Cu, Ta, and Ti.

16. A method of according to claim 14, wherein a thickness of the second conductive layer is substantially equal to a thickness of the dielectric film.

17. A method of according to claim 15, wherein the second conductive layer has a thickness between 400 Å and 1500 Å.

18. A method of according to claim 14, wherein etching the second conductive layer such that the remaining portion of the second conductive layer comprises a middle capacitor electrode comprises:
reactive-ion etching the second conductive layer such that the remaining portion of the second conductive layer comprises a middle capacitor electrode, wherein the middle capacitor electrode is adapted to serve as an upper electrode of a first capacitor structure and a lower electrode of a second capacitor structure.

19. A method of according to claim 1, wherein providing a patterned a middle capacitor electrode is followed by the step of:
depositing a dielectric layer.

20. A method of according to claim 19, wherein depositing a dielectric layer, comprises:
depositing a silicon nitride layer having a thickness between 500 Å and 1500 Å.

21. A method of according to claim 1, wherein providing a patterned second interlayer dielectric layer, comprises the steps of:
providing a second interlayer dielectric layer;
providing a third patterned mask on the second interlayer dielectric layer;
etching away portions of the second interlayer dielectric layer to form a first via opening and a second via opening therein;
removing the third patterned mask from the surface to the second interlayer dielectric layer;
providing a fourth patterned mask on the second interlayer dielectric layer;
etching away other portions of the second interlayer dielectric layer to form a upper capacitor electrode opening therein;
removing the fourth patterned mask from the surface to the second interlayer dielectric layer;
depositing a third conductive layer to simultaneously fill the first via opening, the second via opening, and the upper capacitor electrode opening; and
planarizing the third conductive layer until a surface of the third conductive layer is coplanar with a surface of the second interlayer dielectic layer such that the remaining portions comprise and a upper capacitor electrode, a first via connected to the lower capacitor electrode and the upper capacitor electrode, and a second via connected to the middle electrode plate.

22. The method according to claim 21, wherein depositing a third conductive layer, comprises:
depositing a liner layer;
forming a copper seed layer on the liner layer; and
electroplating copper within the trench to define, at least in part, a lower capacitor electrode.

23. A method of according to claim 21, wherein the second interlayer dielectric layer has a thickness between 3000 Å and 7000 Å.

24. A method of according to claim 21, wherein the third conductive layer consists essentially of copper.

25. A method of according to claim 1, wherein providing a patterned second interlayer dielectric layer having a first via, a second via, and a second interconnection line embedded therein, wherein the second interconnection line is connected to the lower capacitor electrode by the first via, and wherein the second via is connected to the middle capacitor electrode, comprises the steps of:
providing a second interlayer dielectric layer;
providing a third patterned mask on the second interlayer dielectric layer;
etching away portions of the second interlayer dielectric layer to form a first via opening to the lower capacitor electrode and a second via opening to the middle capacitor electrode;
removing the third patterned mask from the surface to the second interlayer dielectric layer;
chemical vapor depositing a third conductive layer to simultaneously fill the first via opening and the second via opening; and
planarizing the third conductive layer until the third conductive layer is flush with a surface of the second interlayer dielectric layer such that the remaining portions comprise a first via connected to the lower capacitor electrode, and a second via connected to the middle capacitor electrode;
providing a fourth conductive layer;
providing a fourth patterned mask on the fourth conductive layer;
reactive ion etching away portions of the fourth conductive layer such that remaining portions of the fourth conductive layer comprise a first interconnection connected to the first via, a top capacitor electrode on the middle capacitor electrode, and a second interconnection connected to the second via;
removing the fourth patterned mask; and
depositing a third interlayer dielectric layer to simultaneously fill spaces adjacent the first interconnection, the top capacitor electrode, and the second interconnection.

26. A method of according to claim 25, wherein the third conductive layer consists essentially of tungsten.

27. A method of according to claim 25, wherein the fourth conductive layer consists essentially of aluminum.

28. A method of according to claim 25, wherein planarizing the third conductive layer until the third conductive layer is flush with a surface of the second interlayer dielectic layer comprises:
chemical mechanical polishing the third conductive layer until the third conductive layer is flush with a surface of the second interlayer dielectic layer.

29. An integrated circuit, comprising:
a lower capacitor electrode having a copper surface coplanar with a surface of a first interlayer dielectric layer laterally surrounding the lower capacitor electrode;
a first conductive via;
a middle capacitor electrode on the lower capacitor electrode;
a dielectric layer interposed between the lower capacitor electrode and the middle capacitor electrode;
a second conductive via directly connected to the middle capacitor electrode;
an upper capacitor electrode surrounded laterally by the second interlayer dielectric layer, wherein the first conductive via connects the upper capacitor electrode to the lower capacitor electrode; and
a second interlayer dielectric layer interposed between the middle capacitor electrode and the upper capacitor electrode.

30. An integrated circuit according to claim 29, wherein the lower capacitor electrode includes a substantially planar face separated from at least a portion of the middle capacitor electrode by the dielectric layer.

31. An integrated circuit according to claim 29, wherein the lower capacitor electrode comprises a copper dual Damascene interconnection line.

32. An integrated circuit according to claim 31, wherein the upper capacitor electrode comprises a copper Damascene interconnection line.

33. An integrated circuit according to claim 31, wherein the middle capacitor electrode is located within a region defined by the copper dual Damascene interconnection line and upper capacitor electrode.

34. An integrated circuit according to claim 32, wherein the middle capacitor electrode is located within a region defined by the copper dual Damascene interconnection line and the copper Damascene interconnection line.

35. An integrated circuit according to claim 29, wherein the upper capacitor electrode comprises aluminum.

36. An integrated circuit according to claim 29, wherein the lower capacitor electrode, middle capacitor electrode, and upper capacitor electrode are each located within a region defined by the first conductive via and the second conductive via.

37. An integrated circuit according to claim 35, wherein the first conductive via comprises a tungsten contact and a aluminum plug.

38. An integrated circuit according to claim 35, wherein the second conductive via comprises a tungsten contact and an aluminum plug, wherein the tungsten contact is directly coupled to the middle capacitor electrode.

39. An integrated circuit according to claim 29, wherein the middle capacitor electrode is located between the first conductive via, the second conductive via, the lower capacitor electrode, and the upper capacitor electrode.

40. An integrated circuit according to claim 32, wherein the middle capacitor electrode is located within a region defined by the first conductive via, the second conductive via, the lower capacitor electrode, and the copper Damascene interconnection line.

41. An integrated circuit according to claim 29, wherein the upper capacitor electrode consists essentially of copper.

42. An integrated circuit according to claim 29, wherein the lower capacitor electrode consists essentially of copper.

43. An integrated circuit according to claim 29, wherein the middle capacitor electrode comprises a metal selected from the group consisting of TiN, W, TaN, Al, Cu, Ta, and Ti.

44. An integrated circuit according to claim 29, wherein the upper capacitor electrode has a thickness between 1000 and 10000 Å.

45. An integrated circuit according to claim 29, wherein the lower capacitor electrode has a thickness between 1500 and 4000 Å.

46. An integrated circuit according to claim 29, wherein the middle capacitor electrode has a thickness between 300 and 1500 Å.

47. An integrated circuit according to claim 29, wherein the lower capacitor electrode, the dielectric layer, and the middle capacitor electrode comprise a first capacitor structure.

48. An integrated circuit according to claim 29, wherein the middle capacitor electrode, second interlayer dielectric layer, and upper capacitor electrode comprise a second capacitor structure.

49. An integrated circuit, comprising:
a lower capacitor electrode having a copper surface coplanar with a surface of a first interlayer dielectric layer laterally surrounding the lower capacitor electrode;
a capacitor dielectric layer extending over at least a portion of the copper surface of the lower capacitor electrode and extending over at least a portion of the first interlayer dielectric layer;
a middle capacitor electrode;
a second interlayer dielectric layer over at least a portion of the capacitor dielectric layer and the middle capacitor electrode; and
an upper capacitor electrode surrounded laterally by the second interlayer dielectric layer.
